(19) United States
(12) Patent Application Publication
(10) Pub. No.: US 2019/0172871 A1
(43) Pub. Date: Jun. 6, 2019

(54) Selector Device Incorporating Conductive Clusters for Memory Applications

(71) Applicant: Avalanche Technology, Inc., Fremont, CA (US)

(72) Inventors: Hongxin Yang, Newark, CA (US); Woojin Kim, Los Altos, CA (US); Yiming Huai, Pleasanton, CA (US)

(21) Appl. No.: 16/251,008

(22) Filed: Jan. 17, 2019

Related U.S. Application Data
(63) Continuation-in-part of application No. 15/157,607, filed on May 18, 2016, now Pat. No. 10,224,367.

(51) Int. Cl. H01L 27/22; H01L 45/00; H01L 43/02; G11C 11/16; H01F 10/32

(52) U.S. Cl. CPC H01L 27/224; H01L 45/1233; H01L 45/1253; H01L 45/146; H01L 43/02; H01L 27/2427; H01F 10/3254; H01F 10/3286; H01L 45/085; H01L 45/06; H01L 45/144; G11C 11/161

(57) ABSTRACT

The present invention is directed to a memory device that includes an array of memory cells. Each of the memory cells includes a memory element connected to a two-terminal selector element. The two-terminal selector element includes a first electrode and a second electrode with a volatile switching layer interposed therebetween. The second electrode is deposited on top of the volatile switching layer during fabrication. The first electrode has a composition comprising a metal element and the second electrode has a composition comprising the metal element and aluminum element. The metal element may be silver, copper, or nickel. The volatile switching layer may have a composite structure comprising a plurality of conductive particles embedded in an insulating matrix. Alternatively, the volatile switching layer may have a multilayer structure comprising one or more conductive layers interleaved with two or more insulating layers. The memory element may include a magnetic tunnel junction.

### CROSS-REFERENCE TO RELATED APPLICATIONS

The present application is a continuation-in-part of the commonly assigned application bearing Ser. No. 15/157,607 filed on May 18, 2016 by Yang et al. and entitled “Selector Device Incorporating Conductive Clusters for Memory Applications,” the content of which is incorporated herein by reference in its entirety.

### BACKGROUND

The present invention relates to a selector device for memory applications, and more particularly, to embodiments of a two-terminal selector device.

A resistance-based memory device normally comprises an array of memory cells, each of which includes a memory element and a selector element coupled in series between two electrodes. The selector element functions like a switch to direct voltage or current through the selected memory element coupled thereto. The selector element may be a three terminal device, such as transistor, or a two-terminal device, such as diode or Ovonic threshold switch (OTS). Upon application of an appropriate voltage or current to the selected memory element, the electrical property of the memory element would change accordingly, thereby switching the stored logic in the respective memory cell.

FIG. 1 is a schematic circuit diagram of a memory array 30, which comprises a plurality of memory cells 32 with each of the memory cells 32 including a two-terminal selector element 34 coupled to a resistance-based memory element 36 in series; a first plurality of parallel wiring lines 38 with each being coupled to a respective row of the memory elements 36 in a first direction; and a second plurality of parallel wiring lines 40 with each being coupled to a respective row of the selector elements 34 in a second direction substantially perpendicular to the first direction. Accordingly, the memory cells 32 are located at the cross points between the first and second plurality of wiring lines 38 and 40.

The resistance-based memory element 36 may be classified into at least one of several known groups based on its resistance switching mechanism. The memory element of Phase Change Random Access Memory (PCRAM) may comprise a phase change chalcogenide compound, which can switch between a resistive phase (amorphous or crystalline) and a conductive crystalline phase. The memory element of Conductive Bridging Random Access Memory (CBRAM) relies on the statistical bridging of metal rich precipitates therein for its switching mechanism. The memory element of CBRAM normally comprises a nominally insulating metal oxide material, which can switch to a lower electrical resistance state as the metal rich precipitates grow and link to form conductive paths upon application of an appropriate voltage. The memory element of Magnetic Random Access Memory (MRAM) typically comprises at least two layers of ferromagnetic materials with an insulating tunnel junction layer interposed therebetween. When a switching current is applied to the memory element of an MRAM device, one of the ferromagnetic layers will switch its magnetization direction with respect to that of the other magnetic layer, thereby changing the electrical resistance of the element.

A magnetic memory element normally includes a magnetic reference layer and a magnetic free layer with an electron tunnel junction layer interposed therebetween. The magnetic reference layer, the electron tunnel junction layer, and the magnetic free layer collectively form a magnetic tunnel junction (MTJ). Upon the application of an appropriate current through the MTJ, the magnetization direction of the magnetic free layer can be switched between two directions: parallel and anti-parallel with respect to the magnetization direction of the magnetic reference layer. The electron tunnel junction layer is normally made of an insulating material with a thickness ranging from a few to a few tens of angstroms. When the magnetization directions of the magnetic free and reference layers are substantially parallel or oriented in a same direction, electrons polarized by the magnetic reference layer can tunnel through the insulating tunnel junction layer, thereby decreasing the electrical resistance of the MTJ. Conversely, the electrical resistance of the MTJ is high when the magnetization directions of the magnetic reference and free layers are substantially anti-parallel or oriented in opposite directions. The stored logic in the magnetic memory element can be switched by changing the magnetization direction of the magnetic free layer between parallel and anti-parallel with respect to the magnetization direction of the reference layer. Therefore, the MTJ has two stable resistance states that allow the MTJ to serve as a non-volatile memory element.

Based on the relative orientation between the magnetic reference and free layers and the magnetization directions thereof, an MTJ can be classified into one of two types: in-plane MTJ, the magnetization directions of which lie substantially within planes parallel to the same layers, or perpendicular MTJ, the magnetization directions of which are substantially perpendicular to the layer planes.

The use of the two-terminal selector element 34 allows the memory cells 32 to attain the minimum cell size of 4F², where F denotes the minimum feature size or one half the minimum feature pitch normally associated with a particular manufacturing process, thereby increasing memory array density. However, conventional bi-directional, two-terminal selector devices, such as Ovonic threshold switch (OTS), have relatively low on/off switching speeds and are prone to current leakage compared with conventional selection transistors.

For the foregoing reasons, there is a need for a two-terminal selector device for memory applications that has high on/off switching speeds and low current leakage and that can be inexpensively manufactured.

### SUMMARY

The present invention is directed to a device that satisfies this need. A memory device having features of the present invention comprises an array of memory cells. Each of the memory cells includes a memory element connected to a two-terminal selector element. The two-terminal selector element includes a first electrode and a second electrode with a volatile switching layer interposed therebetween. The second electrode is deposited on top of the volatile switching layer during fabrication. The first electrode has a composition comprising a metal element and the second electrode has a composition comprising the metal element and aluminum element. The metal element may be silver, copper, or nickel. The volatile switching layer may have a composite structure comprising a plurality of conductive particles embedded in an insulating matrix. Alternatively, the volatile switching layer may have a multilayer structure comprising one or more conductive layers interleaved with two or more insulating layers. The memory element may include a magnetic tunnel junction.

### BRIEF DESCRIPTION OF THE DRAWINGS

These and other features, aspects, and advantages of the present invention will become better understood with regard to the following description, appended claims, and accompanying drawings where:

FIG. 1 is a schematic circuit diagram of a memory array including a plurality of memory cells with each comprising a memory element and a two-terminal selector element coupled in series between two electrodes;

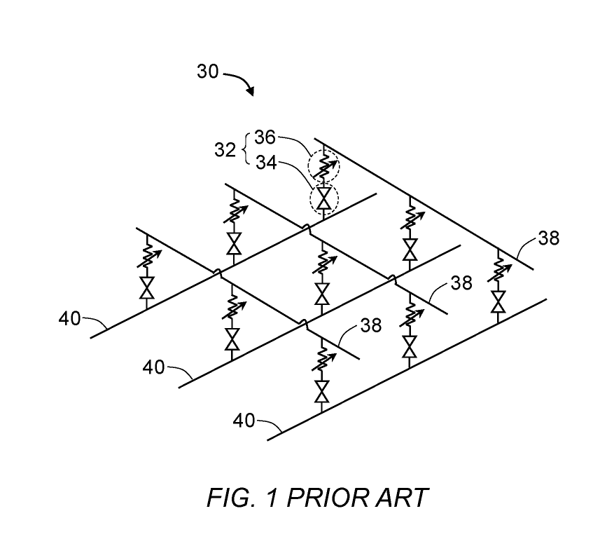

FIG. 2 is a perspective view of a three dimensional memory device in accordance with an embodiment of the present invention;

FIGS. 3A and 3B are cross sectional views of one of memory cells in accordance with different embodiments of the present invention;

FIG. 4 is a cross sectional view of a selector element structure in accordance with an embodiment of the present invention;

FIGS. 5A-5C are cross sectional views of three exemplary structures for the volatile switching layer structure in the selector element of FIG. 4;

FIGS. 6A-6C are cross sectional views of exemplary structures for a volatile switching layer structure having two, three, and four switching layers, respectively;

FIGS. 7A-7F are cross sectional views of exemplary structures for a volatile switching layer structure having two switching layers;

FIGS. 8A-8F are cross sectional views of exemplary structures for a volatile switching layer structure having three switching layers;

FIGS. 9A-9E are cross sectional views showing exemplary structures for the first electrode structure of FIG. 4 having one, two, three, four, and five first electrode layers, respectively;

FIGS. 10A-10E are cross sectional views of exemplary structures for the second electrode structure of FIG. 4 having one, two, three, four, and five second electrode layers, respectively;

FIGS. 11A-11D are cross sectional views of exemplary structures for a magnetic tunnel junction (MTJ) memory element in accordance with an embodiment of the present invention;

FIG. 12A is an I-V response plot for the two-terminal selector element of FIG. 4 as an applied voltage cycles from zero to Vₚ and back;

FIG. 12B is another I-V response plot for the two-terminal selector element of FIG. 4 as an applied voltage cycles from zero to Vₚ and back;

FIGS. 13A-13D illustrate various stages in formation of a conductive path in a volatile switching layer by applying a positive voltage to a top electrode;

FIG. 14 illustrates formation of a conductive path in a switching layer by applying a positive voltage to a bottom electrode; and

FIG. 15 is a cross sectional view of a two-terminal selector element that incorporates therein additional electrode layers in accordance with another embodiment of the present invention.

For purposes of clarity and brevity, like elements and components will bear the same designations and numbering throughout the Figures, which are not necessarily drawn to scale.

### DETAILED DESCRIPTION

Where reference is made herein to a material AB composed of element A and element B, the material AB can be an alloy, a compound, or a combination thereof, except where the context excludes that possibility.

The term “noncrystalline” means an amorphous state or a state in which fine crystals are dispersed in an amorphous matrix, not a single crystal or polycrystalline state. In case of state in which fine crystals are dispersed in an amorphous matrix, those in which a crystalline peak is substantially not observed by, for example, X-ray diffraction can be designated as “noncrystalline.”

The term “at least” followed by a number is used herein to denote the start of a range beginning with that number, which may be a range having an upper limit or no upper limit, depending on the variable being defined. For example, “at least 1” means 1 or more than 1. The term “at most” followed by a number is used herein to denote the end of a range ending with that number, which may be a range having 1 or 0 as its lower limit, or a range having no lower limit, depending upon the variable being defined. For example, “at most 4” means 4 or less than 4, and “at most 40%” means 40% or less than 40%. When, in this specification, a range is given as “a first number to a second number” or “a first number-a second number,” this means a range whose lower limit is the first number and whose upper limit is the second number. For example, “25 to 100 nm” means a range whose lower limit is 25 nm and whose upper limit is 100 nm.

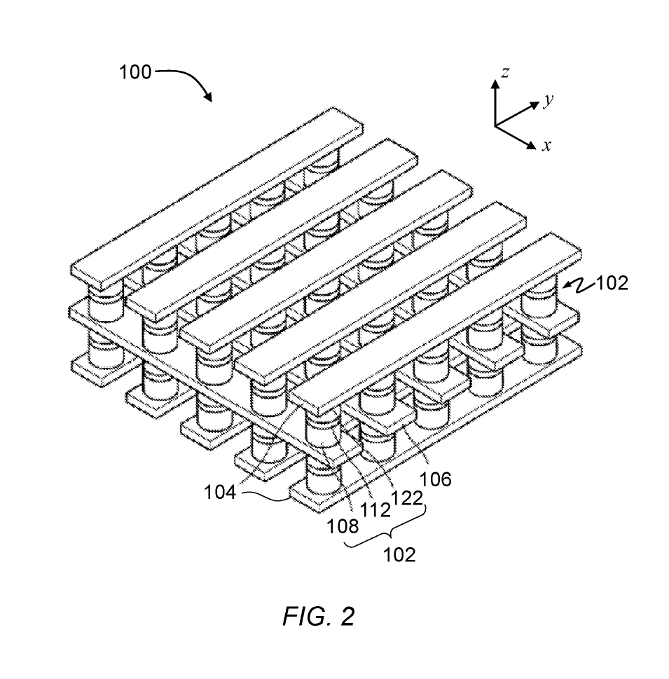

An embodiment of the present invention as applied to a memory device having multiple layers of memory cells will now be described with reference to FIG. 2. Referring now to FIG. 2, the illustrated device comprises two layers of memory cells 102 with each layer of the memory cells 102 formed between a layer of parallel first conductor lines 104 extending along the y-direction and a layer of parallel second conductor lines 106 extending along the x-direction, which is substantially perpendicular to the y-direction. For each layer of the memory cells 102, each of the first conductor lines 104 couples to one ends (top or bottom) of a respective row of the memory cells 102 along the y-direction, while each of the second conductor lines 106 couples to the other ends (top or bottom) of a respective row of the memory cells 102 along the x-direction. Two adjacent layers of the memory cells 102 share a layer of the second conductor lines 106. Accordingly, each of the second conductor lines 106 are coupled to two rows of memory cells thereabove and therebeneath, respectively. For reasons of clarity, only two layers of the memory cells 102 are shown in FIG. 2. However, the present invention can accommodate as many layers of the memory cells 102 as desired. For example, a third layer of memory cells (not shown) may be formed on top of the top layer of the first conductor lines 104 and another layer of the second conductor lines (not shown) may be formed on top of the third layer of memory cells, and so forth. The first and second conductor lines 104 and 106 may operate as word lines and bit lines, respectively, or vice versa. Each of the memory cells 102 includes a memory element 108 and a two-terminal selector element 122 coupled in series. Each of the memory cells 102 may further include an optional intermediate electrode 112 interposed between the memory element 108 and the two-terminal selector element 122.

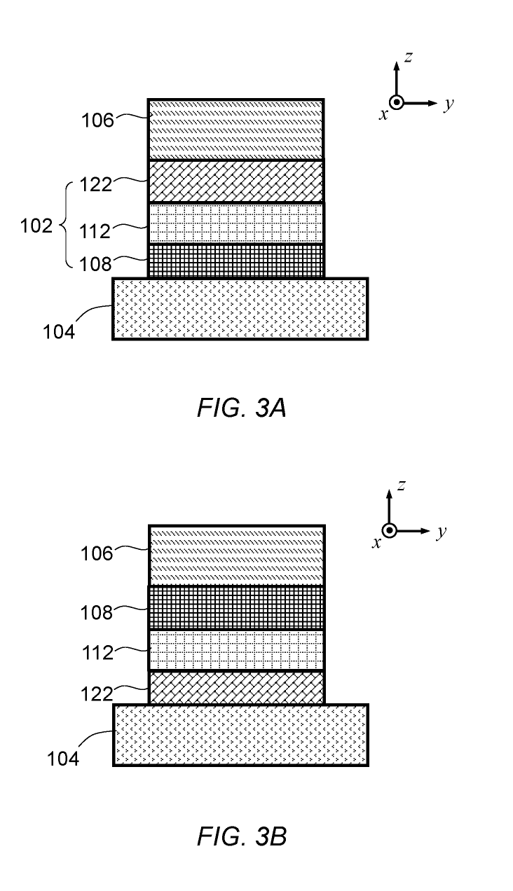

FIG. 3A is a cross sectional view of one of the memory cells 102, which includes the memory element 108 formed on top of one of the first conductor lines 104 extending along the y-direction, the two-terminal selector element 122 formed on top of the memory element 108, and the optional intermediate electrode 112 interposed therebetween. One of the second conductor lines 106 forms on top of the two-terminal selector element 122 and extends along the x-direction. In embodiments where the optional intermediate electrode 112 is absent, the two-terminal selector element 122 is directly coupled to the memory element 108.

The stacking order of the two-terminal selector element 122 and the memory element 108 may alternatively be reversed, as illustrated in FIG. 3B, such that the memory element 108 is formed on top of the two-terminal selector element 122 with the optional intermediate electrode interposed therebetween. Each layer of the memory cells 102 may have the configuration illustrated in FIG. 3A or 3B.

One or more of the first conductor lines 104 and the second conductor lines 106 may be made of any suitable conductor, such as but not limited to copper (Cu), tungsten (W), aluminum (Al), silver (Ag), gold (Au), titanium (Ti), ruthenium (Ru), iridium (Ir), platinum (Pt), palladium (Pd), tantalum (Ta), titanium nitride (TiNₓ), tantalum nitride (TaNₓ), or any combination thereof.

The optional intermediate electrode 112 may be made of any suitable conductor, such as but not limited to copper (Cu), tungsten (W), aluminum (Al), silver (Ag), gold (Au), titanium (Ti), ruthenium (Ru), iridium (Ir), platinum (Pt), palladium (Pd), tantalum (Ta), titanium nitride (TiNₓ), tantalum nitride (TaNₓ), tungsten silicide (WSiₓ), titanium silicide (TiSiₓ), cobalt silicide (CoSiₓ), nickel silicide (NiSiₓ), platinum silicide (PtSix), or any combination thereof.

The memory element 108 may change the resistance state thereof by any suitable switching mechanism, such as but not limited to phase change, precipitate bridging, magnetoresistive switching, or any combination thereof. In one embodiment, the memory element 108 comprises a phase change chalcogenide compound, such as but not limited to Ge₂Sb₂Te₅ or AgInSbTe, which can switch between a resistive phase and a conductive phase. In another embodiment, the memory element 108 comprises a nominally insulating metal oxide material, such as but not limited to NiO, TiO₂, or Sr(Zr)TiO₃, which can switch to a lower electrical resistance state as metal rich precipitates grow and link to form conductive paths upon application of an appropriate voltage. In still another embodiment, the memory element 108 comprises a magnetic free layer and a magnetic reference layer with an insulating electron tunnel junction layer interposed therebetween, collectively forming a magnetic tunnel junction (MTJ). When a switching pulse is applied, the magnetic free layer would switch the magnetization direction thereof, thereby changing the electrical resistance of the MTJ. The magnetic free layer may have a variable magnetization direction substantially perpendicular to a layer plane thereof. The magnetic reference layer may have a fixed magnetization direction substantially perpendicular to a layer plane thereof. Alternatively, the magnetization directions of the magnetic free and reference layers may orientations that are parallel to layer planes thereof.

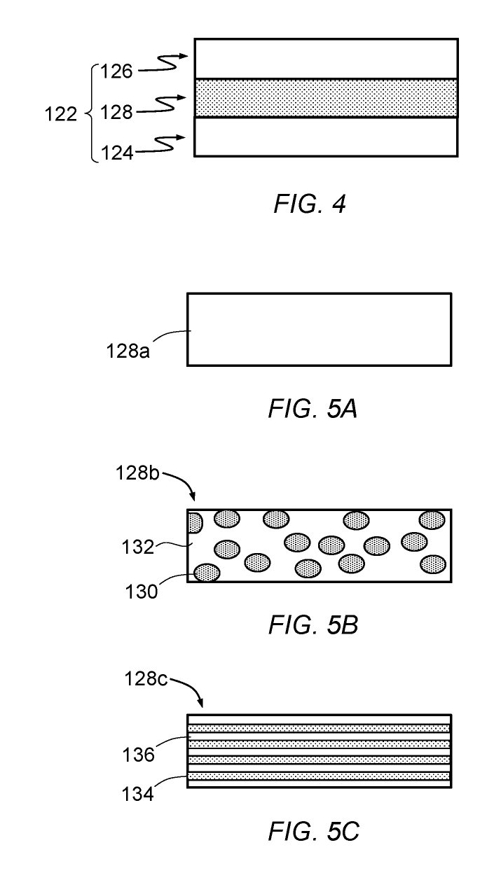

An embodiment of the present invention as applied to the two-terminal selector element 122 will now be described with reference to FIG. 4. Referring now to FIG. 4, the illustrated selector element 122 includes a first electrode structure 124 and a second electrode structure 126 with a volatile switching layer structure 128 interposed therebetween. The second electrode structure 126 may be deposited onto the volatile switching layer structure 128 during fabrication.

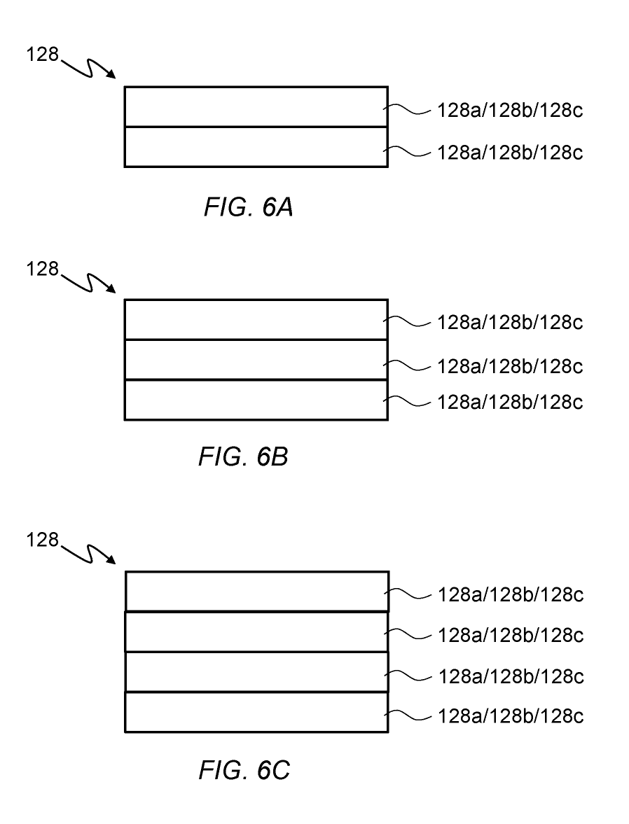

The volatile switching layer structure 128, which may include one or more distinct volatile switching layers, behaves like a volatile device that is nominally insulative in the absence of an applied voltage or current. Upon continuing application of a switching voltage or current, however, the volatile switching layer structure 128 becomes conductive. In an embodiment illustrated in FIG. 5A, the volatile switching layer structure 128 includes a homogeneous layer 128a made of a nominally insulating material or any suitable material that switches its resistance in the presence of an applied field or current, such as but not limited to SiOₓ, SiNₓ, AlOₓ, MgOₓ, TaOₓ, VOₓ, NbOₓ, TiOₓ, WOₓ, HfOₓ, ZrOₓ, NiOₓ, FeOₓ, YOₓ, EuOₓ, SbOₓ, AsOₓ, SbOₓ, SnOₓ, InOₓ, SeOₓ, GaOₓ, CuGeₓS_{y}, CuAgₓGe_{y}S_{z}, GeSbₓTe_{y}, AgInₓSb_{y}Te_{z}, GeTeₓ, SbTeₓ, GeSbₓ, CrOₓ, SrTiₓO_{y}, YZrₓO_{y}, LaFₓ, AgIₓ, CuIₓ, RbAgₓI_{y}, or any combination thereof. The exemplary compounds may be stoichiometric or non-stoichiometric. The homogeneous layer 128a may further include one or more dopant or alloying elements, such as but not limited to Ag, Au, Zn, Sn, Ni, As, and Cu.

Alternatively, the volatile switching layer structure 128 may include a composite layer 128b comprising a plurality of conductive particles or clusters 130 embedded in a nominally insulating matrix 132 as illustrated in FIG. 5B. The conductive particles may have metal-rich compositions. The nominally insulating matrix 132 may be made of any suitable material, such as but not limited to SiOₓ, SiNₓ, AlOₓ, MgOₓ, TaOₓ, VOₓ, NbOₓ, TiOₓ, WOₓ, HfOₓ, ZrOₓ, NiOₓ, FeOₓ, YOₓ, EuOₓ, SrOₓ, AsOₓ, SbOₓ, SnOₓ, InOₓ, SeOₓ, GaOₓ, CeOₓ, TeOₓ, CuGeₓS_{y}, CuAgₓGe_{y}S_{z}, GeSbₓTe_{y}, AgInₓSb_{y}Te_{z}, GeTeₓ, SbTeₓ, GeSbₓ, CrOₓ, SrTiₓO_{y}, YZrₓO_{y}, LaFₓ, AgIₓ, CuIₓ, RbAgₓI_{y}, or any combination thereof. The exemplary compounds may be stoichiometric or non-stoichiometric.

With continuing reference to FIG. 5B, the plurality of conductive particles or clusters 130 may be made of a relatively inert metal, or an alloy including one or more inert metals, or a fast electric field enhanced diffuser material, or any combination thereof. Examples of the inert metal include gold (Au), silver (Ag), platinum (Pt), palladium (Pd), rhodium (Rh), iridium (Ir), ruthenium (Ru), osmium (Os), rhenium (Re), and any combinations thereof. Examples of the fast electric field enhanced diffuser material include nickel (Ni), copper (Cu), silver (Ag), gold (Au), zinc (Zn), cobalt (Co), iron (Fe), tungsten (W), molybdenum (Mo), tantalum (Ta), niobium (Nb), aluminum (Al), titanium (Ti), zirconium (Zr), arsenic (As), titanium nitride (TiNₓ), zirconium nitride (ZrNₓ), tantalum nitride (TaNₓ), niobium nitride (NbNₓ), tungsten nitride (WNₓ), and any combinations thereof. The exemplary nitrides may be stoichiometric or non-stoichiometric.

The composite layer structure 128b shown in FIG. 5B may be fabricated by co-sputtering, whereby the target for the plurality of conductive particles or clusters 130 and the target for the insulating matrix 132 are sputtered at the same time. Alternatively, the composite layer structure 128b may be fabricated by alternating sputter deposition of materials corresponding to the conductive particles or clusters 130 and the insulating matrix 132. The sputter-deposited film by both methods may subsequently subjected to an annealing process to enhance the diffusion or precipitation of the conductive particles or clusters 130.

Still alternatively, the volatile switching layer structure 128 may have a multilayer structure 128c comprising one or more conductive layers 134 interleaved with two or more insulating layers 136 as illustrated in FIG. 5C. The conductive layers 134 may be made of any of the suitable conductive materials described above for the conductive particles or clusters 130. The thickness of the conductive layers 134 may range from several angstroms to several nanometers. In some cases where the conductive layers 134 are extremely thin, one or more of the conductive layers 134 may be punctured by holes, thereby rendering the layer coverage to be discontinuous in some regions. Similarly, the nominally insulating layers 136 may be made of any of the suitable insulating materials described above for the matrix 132. In an embodiment, the thicknesses of the conductive layers 134 decrease and/or the thicknesses of the insulating layers 136 increase along the direction of the anti-parallelizing current.

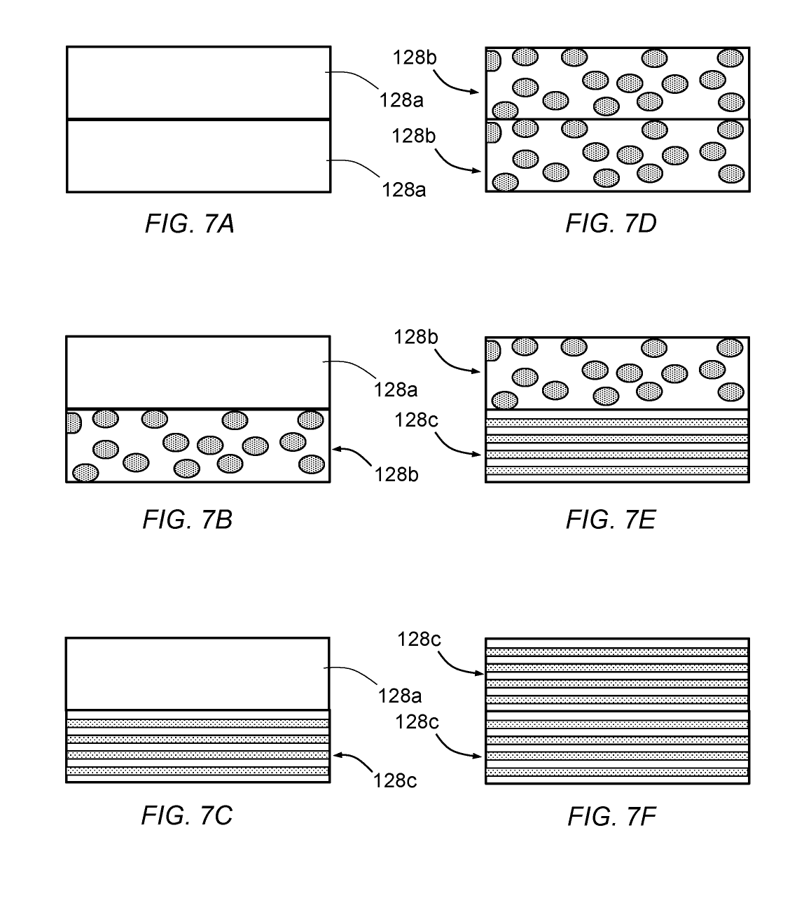

The volatile switching layer structure 128 may alternatively include two or more volatile switching layers with each switching layer being a homogenous layer 128a, a composite layer 128b, or a multilayer structure 128c. FIGS. 6A-6C illustrate the volatile switching layers structure 128 including two, three, and four switching layers, respectively.

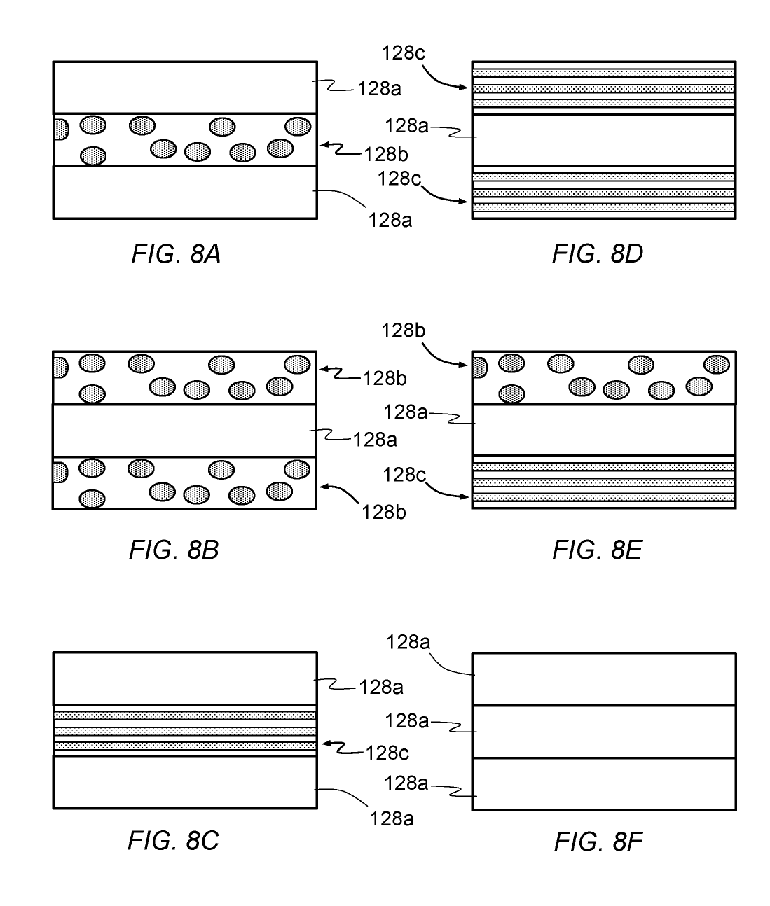

Some examples of the volatile switching layer structure 128 having two switching layers are illustrated in FIGS. 7A-7F. FIG. 7A shows an exemplary structure having two homogenous layers 128a, which may be made of different materials and/or having different dopants if present. FIG. 7B shows another exemplary structure including a homogenous layer 128a and a composite layer 128b. In an embodiment, the homogenous layer 128a and the matrix 132 of the composite layer 128b are made of the same material. In an alternative embodiment, the homogenous layer 128a and the matrix 132 of the composite layer 128b are made of different materials. FIG. 7C shows still another exemplary structure including a homogenous layer 128a and a multilayer structure 128c. In an embodiment, the homogenous layer 128a and the insulating layers 136 of the multilayer structure 128c are made of the same material. In an alternative embodiment, the homogenous layer 128a and the insulating layers 136 of the multilayer structure 128c are made of different materials. FIG. 7D shows yet another exemplary structure including two composite layer 128b, which may have different materials for the matrix 132 and/or different materials for the conductive particles or clusters 130. FIG. 7E shows still yet another exemplary structure including a composite layer 128b and a multilayer structure 128c. The matrix 132 of the composite layers 128b and the insulating layers 136 of the multilayer structure 128c may be made of the same material or different materials. Likewise, the conductive particles or clusters 130 of the composite layer 128b and the conductive layers 134 of the multilayer structure 128c may be made of the same material or different materials. FIG. 7F shows yet still another exemplary structure including two multilayer structures 128c, which may have different materials for the insulating layers 136 and/or different materials for the conductive layers 134. Moreover, the stacking order of the volatile switching layers in the exemplary structures illustrated in FIGS. 7A-7F may be inverted.

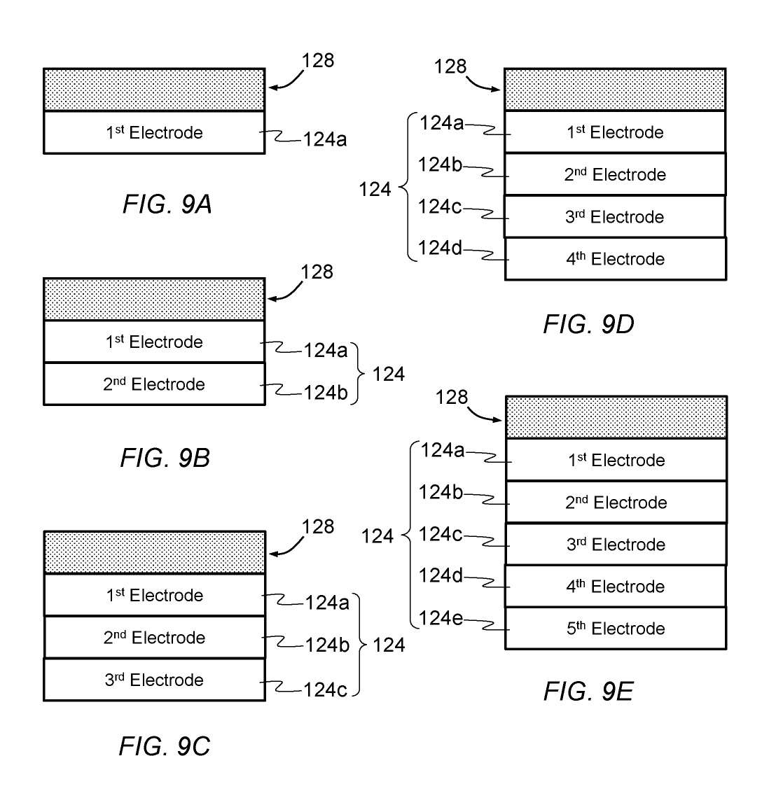

Some examples of the volatile switching layer structure 128 having three switching layers are illustrated in FIGS. 8A-8F. FIG. 8A shows an exemplary structure including two homogenous layers 128a with a composite layer 128b interposed therebetween. The two homogenous layers 128a may be made of the same material or different materials. The matrix 132 of the composite layer 128b and at least one of the two homogeneous layers 128a may be made of the same material. Alternatively, the matrix 132 of the composite layer 128b may be made of a different material from the two homogeneous layers 128a.

FIG. 8B shows another exemplary structure including two composite layers 128b with a homogeneous layer 128a interposed therebetween. The matrices 132 of the two composite layers 128b may be made of the same material or different materials. The conductive particles or clusters 130 of the two composite layers 128b may be made of the same material or different materials. The homogeneous layer 128a and at least one of the two matrices 132 of the two composite layers 128b may be made of the same material. Alternatively, the homogeneous layer 128a may be made of a different material from the two matrices 132 of the two composite layers 128b.

FIG. 8C illustrates still another exemplary structure including two homogenous layers 128a with a multilayer structure 128c interposed therebetween. The two homogenous layers 128a may be made of the same material or different materials. The insulating layers 136 of the multilayer structure 128c and at least one of the two homogeneous layers 128a may be made of the same material. Alternatively, the insulating layers 136 of the multilayer structure 128c may be made of a different material from the two homogeneous layers 128a.

FIG. 8D illustrates yet another exemplary structure including two multilayer structures 128c with a homogeneous layer 128a interposed therebetween. The insulating layers 136 of the two multilayer structures 128c may be made of the same material or different materials. Likewise, the conductive layers 134 of the two multilayer structures 128c may be made of the same material or different materials. The homogeneous layer 128a and at least one of the two stacks of insulating layers 136 of the two multilayer structures 128c may be made of the same material. Alternatively, the homogeneous layer 128a may be made of a different material from the insulating layers 136 of the two multilayer structures 128c.

FIG. 8E shows still yet another exemplary structure including a composite layer 128b and a multilayer structure 128c with a homogeneous layer 128a interposed therebetween. The matrix 132 of the composite layer 128b and the insulating layers 136 of the multilayer structure 128c may be made of the same material or different materials. The conductive particles or clusters 130 of the composite layer 128b and the conductive layers 134 of the multilayer structure 128c may be made of the same material or different materials. The homogeneous layer 128a and at least one of the matrix 132 of the composite layer 128b and the insulating layers 136 of the multilayer structure 128c may be made of the same material. Alternatively, the homogeneous layer 128a may be made of a different material from the matrix 132 of the composite layer 128b and the insulating layers 136 of the multilayer structure 128c.

FIG. 8F illustrates yet still another exemplary structure including three homogeneous layers 128a. The three homogeneous layers 128a may be made of different materials and/or have different dopants if present. In an embodiment, the interposing homogenous layer 128a is made of a different material from the two peripheral homogeneous layers 128a, which may be made of the same material and/or have the same dopant if present.

The stacking order of the volatile switching layers in the exemplary structures illustrated in FIGS. 8A-8F may be inverted.

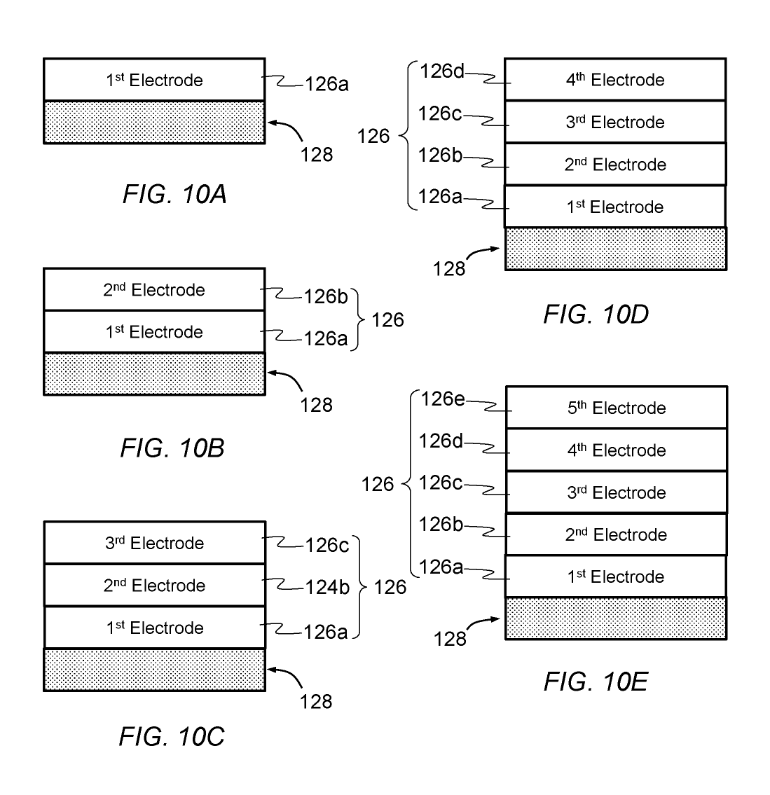

Referring back to FIG. 4, the first electrode structure 124 and the second electrode structure 126 of the selector element 122 each may include one or more electrode layers. FIGS. 9A-9E show partial views of the selector element 122 including the volatile switching layer structure 128 and various exemplary structures for the first electrode structure 124.

FIG. 9A illustrates an exemplary structure for the first electrode structure 124 that includes a first electrode layer 124a formed adjacent to the volatile switching layer structure 128.

FIG. 9B illustrates another exemplary structure for the first electrode structure 124 that includes the first electrode layer 124a formed adjacent to the volatile switching layer structure 128 and a second electrode layer 124b formed adjacent to the first electrode layer 124a opposite the volatile switching layer structure 128.

FIG. 9C illustrates still another exemplary structure for the first electrode structure 124 that includes the first electrode layer 124a formed adjacent to the volatile switching layer structure 128, the second electrode layer 124b formed adjacent to the first electrode layer 124a opposite the volatile switching layer structure 128, and a third electrode layer 124c formed adjacent to the second electrode layer 124b opposite the first electrode layer 124a.

FIG. 9D illustrates yet another exemplary structure for the first electrode structure 124 that includes the first electrode layer 124a formed adjacent to the volatile switching layer structure 128, the second electrode layer 124b formed adjacent to the first electrode layer 124a opposite the volatile switching layer structure 128, the third electrode layer 124c formed adjacent to the second electrode layer 124b opposite the first electrode layer 124a, and a fourth electrode layer 124d formed adjacent to the third electrode layer 124c opposite the second electrode layer 124b.

FIG. 9E illustrates still yet another exemplary structure for the first electrode structure 124 that includes the first electrode layer 124a formed adjacent to the volatile switching layer structure 128, the second electrode layer 124b formed adjacent to the first electrode layer 124a opposite the volatile switching layer structure 128, the third electrode layer 124c formed adjacent to the second electrode layer 124b opposite the first electrode layer 124a, the fourth electrode layer 124d formed adjacent to the third electrode layer 124c opposite the second electrode layer 124b, and a fifth electrode layer 124e formed adjacent to the fourth electrode layer 124d opposite the third electrode layer 124c.

The first, second, third, fourth, and fifth electrode layers 124a-124e of the first electrode structure 124 each may include one or more of the following elements: Au, Ag, Cu, Pt, Pd, Ni, Ir, Rh, Co, Os, Ru, Fe, Re, Mn, W, Mo, Cr, Ta, Nb, V, Hf, Zr, Ti, Mg, Zn, Cd, In, Ga, Al, B, Pb, Sn, Ge, Si, C, Bi, Sb, As, N, Te, Se, and O to form a suitable conductor material, such as but not limited to Au, Ag, Pt, Pd, Rh, Ir, Ru, Re, Si, Ni, NiSiₓ, NiCrₓ, Cu, CuSiₓ, CuGeₓ, CuAlₓ, CuNₓ, Co, CoSiₓ, CoCrₓ, Zn, ZnNₓ, Fe, FeNiₓCr_{y}, Cr, CrSiₓ Al, AlNₓ, Ti, TiSiₓ, TiNₓ, Ta, TaSiₓ, TaNₓ, W, WSiₓ, WNₓ, Mo, MoSiₓ, MoNₓ, Zr, ZrSiₓ, ZrNₓ, Hf, HfSiₓ, HfNₓ, Nb, NbSiₓ, NbNₓ, V, VSiₓ, VNₓ, TiAlₓ, NiAlₓ, CoAlₓ, AgOₓ, CuOₓ, NiOₓ, or any combination thereof. For example and without limitation, the first and second electrode layers 124a and 124b may be made of AgOₓ and Ag, respectively. Alternatively, the first and second electrode layers 124a and 124b may be made of TiNₓ and Ag, respectively. Still alternatively, the first and second electrode layers 124a and 124b may be made of TiNₓ and AgAlₓ, respectively.

One or more of the first, second, third, fourth, and fifth electrode layers 124a-124e of the first electrode structure 124 each may alternatively have a multilayer structure formed by interleaving one or more layers of a first material with one or more layers of a second material. The first and second materials each may include one or more of the following elements: Au, Ag, Cu, Pt, Pd, Ni, Ir, Rh, Co, Os, Ru, Fe, Re, Mn, W, Mo, Cr, Ta, Nb, V, Hf, Zr, Ti, Mg, Zn, Cd, In, Ga, Al, B, Pb, Sn, Ge, Si, C, Bi, Sb, As, N, Te, Se, and O to form a suitable conductive material, such as but not limited to Au, Ag, Pt, Pd, Rh, Ir, Ru, Re, Si, Ni, NiSiₓ, NiCrₓ, Cu, CuSiₓ, CuGeₓ, CuAlₓ, CuNₓ, Co, CoSiₓ, CoCrₓ, Zn, ZnNₓ, Fe, FeNiₓCr_{y}, Cr, CrSiₓ Al, AlNₓ, Ti, TiSiₓ, TiNₓ, Ta, TaSiₓ, TaNₓ, W, WSiₓ, WNₓ, Mo, MoSiₓ, MoNₓ, Zr, ZrSiₓ, ZrNₓ, Hf, HfSiₓ, HfNₓ, Nb, NbSiₓ, NbNₓ, V, VSiₓ, VNₓ, TiAlₓ, NiAlₓ, CoAlₓ, AgOₓ, CuOₓ, NiOₓ, or any combination thereof.

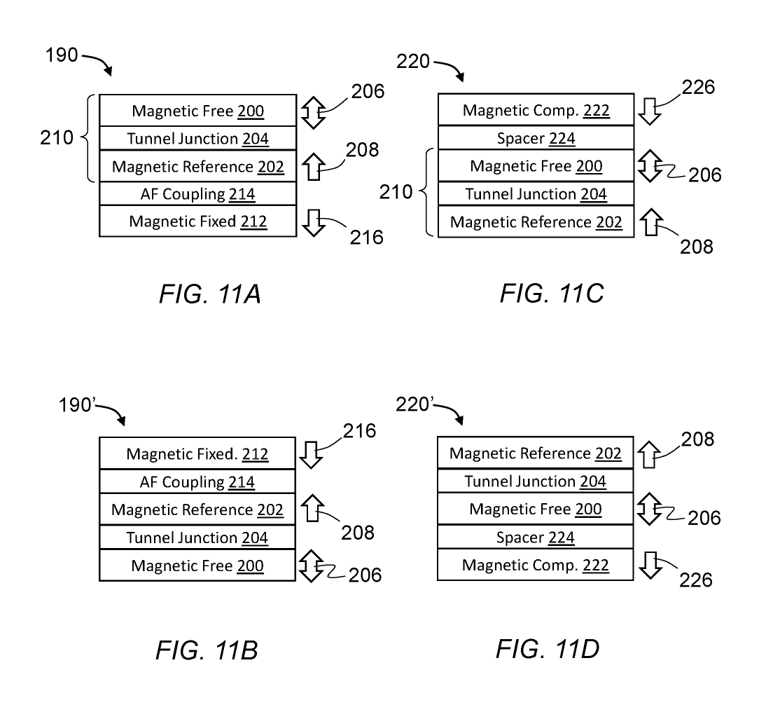

FIGS. 10A-10E show partial views of the selector element 122 including the volatile switching layer structure 128 and various exemplary structures for the second electrode structure 126. FIG. 10A illustrates an exemplary structure for the second electrode structure 126 that includes a first electrode layer 126a formed adjacent to the volatile switching layer structure 128.

FIG. 10B illustrates another exemplary structure for the second electrode structure 126 that includes the first electrode layer 126a formed adjacent to the volatile switching layer structure 128 and a second electrode layer 126b formed adjacent to the first electrode layer 126a opposite the switching layer structure 128.

FIG. 10C illustrates still another exemplary structure for the second electrode structure 126 that includes the first electrode layer 126a formed adjacent to the volatile switching layer structure 128, the second electrode layer 126b formed adjacent to the first electrode layer 126a opposite the volatile switching layer structure 128, and a third electrode layer 126c formed adjacent to the second electrode layer 126b opposite the first electrode layer 126a.

FIG. 10D illustrates yet another exemplary structure for the second electrode structure 126 that includes the first electrode layer 126a formed adjacent to the volatile switching layer structure 128, the second electrode layer 126b formed adjacent to the first electrode layer 126a opposite the volatile switching layer structure 128, the third electrode layer 126c formed adjacent to the second electrode layer 126b opposite the first electrode layer 126a, and a fourth electrode layer 126d formed adjacent to the third electrode layer 126c opposite the second electrode layer 126b.

FIG. 10E illustrates still yet another exemplary structure for the second electrode structure 126 that includes the first electrode layer 126a formed adjacent to the volatile switching layer structure 128, the second electrode layer 126b formed adjacent to the first electrode layer 126a opposite the volatile switching layer structure 128, the third electrode layer 126c formed adjacent to the second electrode layer 126b opposite the first electrode layer 126a, the fourth electrode layer 126d formed adjacent to the third electrode layer 126c opposite the second electrode layer 126b, and a fifth electrode layer 126e formed adjacent to the fourth electrode layer 126d opposite the third electrode layer 126c.

The first, second, third, fourth, and fifth electrode layers 126a-126e of the second electrode structure 126 each may include one or more of the following elements: Au, Ag, Cu, Pt, Pd, Ni, Ir, Rh, Co, Os, Ru, Fe, Re, Mn, W, Mo, Cr, Ta, Nb, V, Hf, Zr, Ti, Mg, Zn, Cd, In, Ga, Al, B, Pb, Sn, Ge, Si, C, Bi, Sb, As, N, Te, Se, and O to form a suitable conductive material, such as but not limited to Au, Ag, Pt, Pd, Rh, Ir, Ru, Re, Si, Ni, NiSiₓ, NiCrₓ, Cu, CuSiₓ, CuGeₓ, CuAlₓ, CuNₓ, Co, CoSiₓ, CoCrₓ, Zn, ZnNₓ, Fe, FeNiₓCr_{y}, Cr, CrSiₓ Al, AlNₓ, Ti, TiSiₓ, TiNₓ, Ta, TaSiₓ, TaNₓ, W, WSiₓ, WNₓ, Mo, MoSiₓ, MoNₓ, Zr, ZrSiₓ, ZrNₓ, Hf, HfSiₓ, HfNₓ, Nb, NbSiₓ, NbNₓ, V, VSiₓ, VNₓ, TiAlₓ, NiAlₓ, CoAlₓ, AgOₓ, CuOₓ, NiOₓ, or any combination thereof. For example and without limitation, the first and second electrode layers 126a and 126b may be made of AgOₓ and Ag, respectively. Alternatively, the first and second electrode layers 126a and 126b may be made of TiNₓ and Ag, respectively. Still alternatively, the first and second electrode layers 126a and 126b may be made of TiNₓ and AgAlₓ, respectively.

One or more of the first, second, third, fourth, and fifth electrode layers 126a-126e of the second electrode structure 126 each may alternatively have a multilayer structure formed by interleaving one or more layers of a first material with one or more layers of a second material. The first and second materials each may include one or more of the following elements: Au, Ag, Cu, Pt, Pd, Ni, Ir, Rh, Co, Os, Ru, Fe, Re, Mn, W, Mo, Cr, Ta, Nb, V, Hf, Zr, Ti, Mg, Zn, Cd, In, Ga, Al, B, Pb, Sn, Ge, Si, C, Bi, Sb, As, N, Te, Se, and O to form a suitable conductive material, such as but not limited to Au, Ag, Pt, Pd, Rh, Ir, Ru, Re, Si, Ni, NiSiₓ, NiCrₓ, Cu, CuSiₓ, CuGeₓ, CuAlₓ, CuNₓ, Co, CoSiₓ, CoCrₓ, Zn, ZnNₓ, Fe, FeNiₓCr_{y}, Cr, CrSiₓ Al, AlNₓ, Ti, TiSiₓ, TiNₓ, Ta, TaSiₓ, TaNₓ, W, WSiₓ, WNₓ, Mo, MoSiₓ, MoNₓ, Zr, ZrSiₓ, ZrNₓ, Hf, HfSiₓ, HfNₓ, Nb, NbSiₓ, NbNₓ, V, VSiₓ, VNₓ, TiAlₓ, NiAlₓ, CoAlₓ, AgOₓ, CuOₓ, NiOₓ, or any combination thereof.

Referring again to FIG. 4, the first electrode structure 124 and the second electrode structure 126 of the selector element 122 may have a “asymmetric” configuration, whereby the two electrode structures 124 and 126 have different numbers of electrode layers and/or different conductive materials for comparable electrode layers (e.g., the first electrode layer 124a and the first electrode layer 126a are made of different materials). For example and without limitation, an asymmetric selector element 122 may comprise a first electrode structure 124 that includes a first electrode layer 124a made of silver, a second electrode structure 126 that includes a first electrode layer 126a made of copper, and a volatile switching layer structure 128 including a plurality of silver particles or clusters 130 embedded in a hafnium oxide matrix 132 as illustrated in FIG. 5B or at least one layer of silver 134 interleaved with two or more layers of hafnium oxide 136 as illustrated in FIG. 5C. The second electrode structure 126 of the above exemplary asymmetric selector element may alternatively include a first electrode layer 126a made of titanium nitride and a second electrode layer 126b made of silver. In an embodiment, the plurality of conductive particles or clusters 130 or the conductor layers 134 in the volatile switching layer structure 128 are made of the same material as at least one electrode layer in at least one of the first and second electrode structures 124 and 126. For example and without limitation, the plurality of conductive particles or clusters 130 and the second electrode layer 126b of the second electrode structure 126 both may be made of Ag, Cu, Co, Ni, or any combination thereof.

The first electrode structure 124 and the second electrode structure 126 of the selector element 122 may alternatively have a “symmetric” configuration, whereby the two electrode structures 124 and 126 have the same number of electrode layers and the same conductive material for comparable electrode layers (i.e., the first electrode layer 124a and the first electrode layer 126a are made of the same material, the second electrode layer 124b and the second electrode layer 126b are made of the same material, and so on).

In an embodiment for the selector element 122 with the symmetric electrode configuration, the volatile switching layer structure 128 includes a plurality of conductive particles or clusters 130 embedded in a matrix 132. The conductive particles or clusters 130 are made of Ag, Au, Ni, Cu, Co, As, or any combination thereof, while the matrix 132 is made of HfOₓ, ZrOₓ, TiOₓ, NiOₓ, YOₓ, AlOₓ, MgOₓ, TaOₓ, SiOₓ, or any combination thereof. The volatile switching layer structure 128 may have an alternative structure that includes one or more conductive layers 134 interleaved with two or more insulating layers 136. The conductive layers 134 are made of Ag, Au, Ni, Cu, Co, Ta, As, or any combination thereof, while the insulating layers 136 are made of HfOₓ, ZrOₓ, TiOₓ, NiOₓ, YOₓ, AlOₓ, MgOₓ, TaOₓ, SiOₓ, or any combination thereof. The first and second electrode structures 124 and 126 of the selector element 122 with the symmetric electrode configuration include the first electrode layers 124a and 126a made of a material that may interact with defects or ions in the volatile switching layer structure 128 in the presence of an electric field, such as but not limited to Ag, Au, Ni, Cu, Co, Ta, Ti, Al, or any combination thereof, thereby acting as “active” electrodes. The first and second electrode structures 124 and 126 may further include the second electrode layers 124b and 126b that may be relatively inert with respect to the defects or ions in the volatile switching layer structure 128, such as but not limited to Pt, Pd, Rh, Ir, Ru, Re, Ta, TiNₓ, ZrNₓ, HfNₓ, TaNₓ, NbNₓ, TiSiₓ, CoSiₓ, NiSiₓ, or any combination thereof, thereby acting as “inert” electrodes.

In another embodiment for the selector element 122 with the symmetric electrode configuration, the volatile switching layer structure 128 includes a plurality of conductive particles or clusters 130 embedded in a matrix 132. The conductive particles or clusters 130 are made of Ag, Au, Ni, Cu, Co, As, or any combination thereof, while the matrix 132 is made of HfOₓ, ZrOₓ, TiOₓ, NiOₓ, YOₓ, AlOₓ, MgOₓ, TaOₓ, SiOₓ, or any combination thereof. The volatile switching layer structure 128 may have an alternative structure that includes one or more conductive layers 134 interleaved with two or more insulating layers 136. The conductive layers 134 are made of Ag, Au, Ni, Cu, Co, Ta, As, or any combination thereof, while the insulating layers 136 are made of HfOₓ, ZrOₓ, TiOₓ, NiOₓ, YOₓ, AlOₓ, MgOₓ, TaOₓ, SiOₓ, or any combination thereof. The first and second electrode structures 124 and 126 of the selector element 122 with the symmetric electrode configuration include the first electrode layers 124a and 126a made of a material that may be relatively inert and may not interact with defects or ions in the volatile switching layer structure 128 in the presence of an electric field, such as but not limited to Pt, Pd, Rh, Ir, Ru, Re, Ta, TiNₓ, ZrNₓ, HfNₓ, TaNₓ, NbNₓ, TiSiₓ, CoSiₓ, NiSiₓ, or any combination thereof; and the second electrode layers 124b and 126b that may act as active electrodes and are made of a material that may interact with defects or ions in the volatile switching layer structure 128 in the presence of an electric field, such as but not limited to Ag, Au, Ni, Cu, Co, Ta, Ti, Al, or any combination thereof. In addition to being relatively inert, the first electrode layers 124a and 126a may serve as diffusion barrier for the movement of defects or ions between the volatile switching layer structure 128 and the second electrode layers 124b and 126b. The first and second electrode structures 124 and 126 may further include the third electrode layers 124c and 126c that may be relatively inert and may not interact with defects or ions in the volatile switching layer structure 128. For example and without limitation, the third electrode layers 124c and 126c may be made of Pt, Pd, Rh, Ir, Ru, Re, Ta, TiNₓ, ZrNₓ, HfNₓ, CoSiₓ, NiSiₓ, or any combination thereof.

In still another embodiment for the selector element 122 with the symmetric electrode configuration, the plurality of conductive particles or clusters 130 or the conductive layers 134 in the volatile switching layer structure 128 are made of the same material as at least one electrode layer in the first and second electrode structures 124 and 126. For example and without limitation, the plurality of conductive particles or clusters 130 and the second electrode layers 124b and 126b may be made of Ag, Cu, Co, Ni, or any combination thereof.

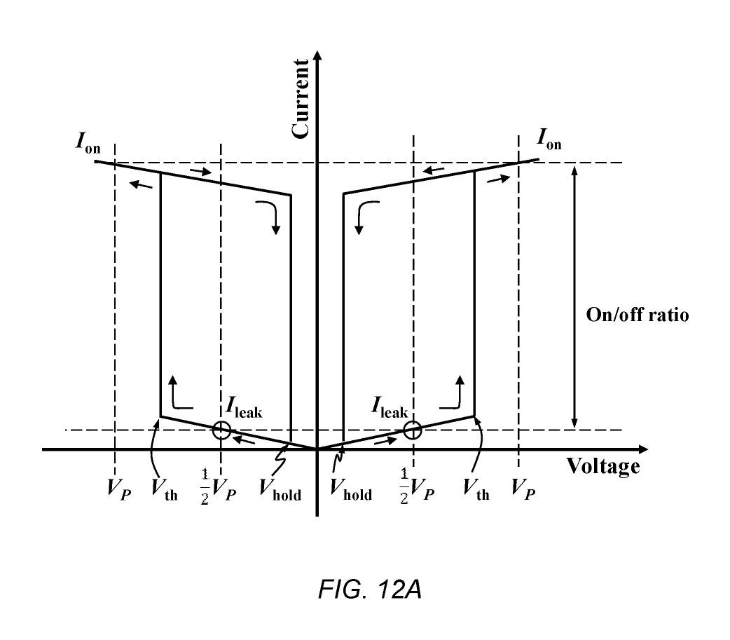

FIG. 11A shows an exemplary MTJ structure 190 for the memory element 108 that includes a magnetic free layer structure 200 and a magnetic reference layer structure 202 with a tunnel junction layer 204 interposed therebetween. The magnetic free layer structure 200 has a variable magnetization direction 206 substantially perpendicular to the layer plane thereof. The magnetic reference layer structure 202 has a first invariable magnetization direction 208 substantially perpendicular to the layer plane thereof. The magnetic free layer structure 200, the tunnel junction layer 204, and the magnetic reference layer structure 202 collectively form a magnetic tunnel junction structure 210. The exemplary MTJ structure 190 may further include a magnetic fixed layer structure 212 exchange coupled to the magnetic reference layer structure 202 through an anti-ferromagnetic coupling layer 214. The magnetic fixed layer structure 212 has a second invariable magnetization direction 216 that is substantially perpendicular to the layer plane thereof and is substantially opposite to the first invariable magnetization direction 208 of the magnetic reference layer structure 202. In an embodiment, the switching voltage of the exemplary structure 190 from the low resistance state to the high resistance state is substantially same as the switching voltage from the high resistance state to the low resistance state by adjusting the offset field, which is the net external magnetic field acting on the magnetic free layer structure 200 along the direction of perpendicular magnetization 208. In another embodiment, the stray magnetic fields exerted on the magnetic free layer structure 200 by the magnetic reference and fixed layer structures 202 and 212, respectively, substantially cancel each other, thereby rendering the offset field to be substantially zero or negligible. The stacking order of the layers 212, 214, 202, 204, and 200 in the exemplary structure 190 may be inverted as shown in FIG. 11B.

Another exemplary MTJ structure 220 for the memory element 108, as illustrated in FIG. 11C, includes the magnetic tunnel junction structure 210 and a magnetic compensation layer structure 222 separated from the magnetic free layer structure 200 by a non-magnetic spacer layer 224. The magnetic compensation layer structure 222 has a third invariable magnetization direction 226 that is substantially perpendicular to the layer plane thereof and is substantially opposite to the first invariable magnetization direction 208 of the magnetic reference layer structure 202. The magnetic compensation layer structure 222 may be used to generate a magnetic field opposing that exerted by the magnetic fixed layer structure 202 on the magnetic free layer structure 200. In an embodiment, the switching voltage of the exemplary structure 220 from the low resistance state to the high resistance state is substantially same as the switching voltage from the high resistance state to the low resistance state by adjusting the offset field. In another embodiment, the stray magnetic fields exerted on the magnetic free layer structure 200 by the magnetic reference and compensation layer structures 202 and 222, respectively, substantially cancel each other, thereby rendering the offset field to be substantially zero or negligible. The stacking order of the layers 202, 204, 200, 224, and 222 in the exemplary MTJ structure 220 may be inverted as shown in FIG. 11D.

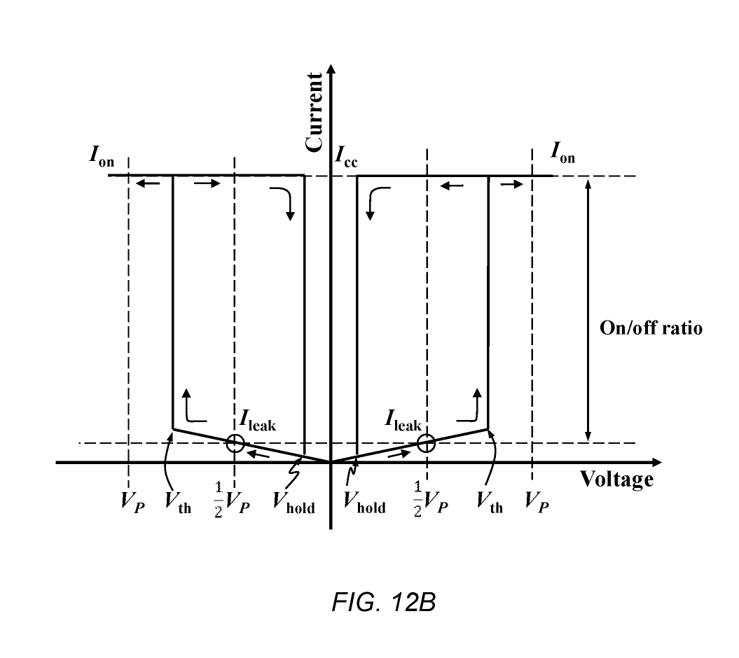

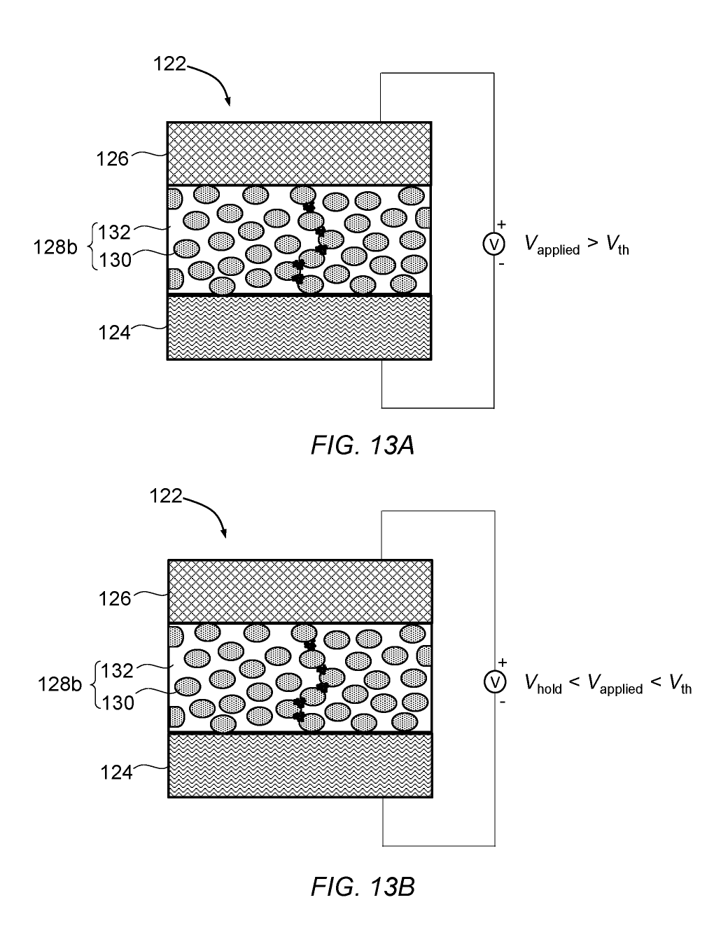

Operation of the two-terminal selector element 110 will now be described with reference to the current-voltage (I-V) response plot illustrated in FIG. 12A. The I-V plot shows the magnitude of electric current passing through the two-terminal selector element 122 as the voltage applied to the selector element 122 varies. Initially, the current gradually increases with the applied voltage from zero to near a threshold voltage, Vₜₕ. At or near Vₜₕ, the current rapidly increases and exhibits a highly non-linear behavior. As the voltage continues to increase beyond Vₜₕ, the current increase becomes gradual again until reaching Iₒₙ and corresponding voltage Vₚ, which are programming current and voltage for the memory element 108, respectively. The current response behaves like a step function as the applied voltage increases from zero to Vₚ with the sharp increase occurring at or near Vₜₕ, which may include a narrow range of voltage values.

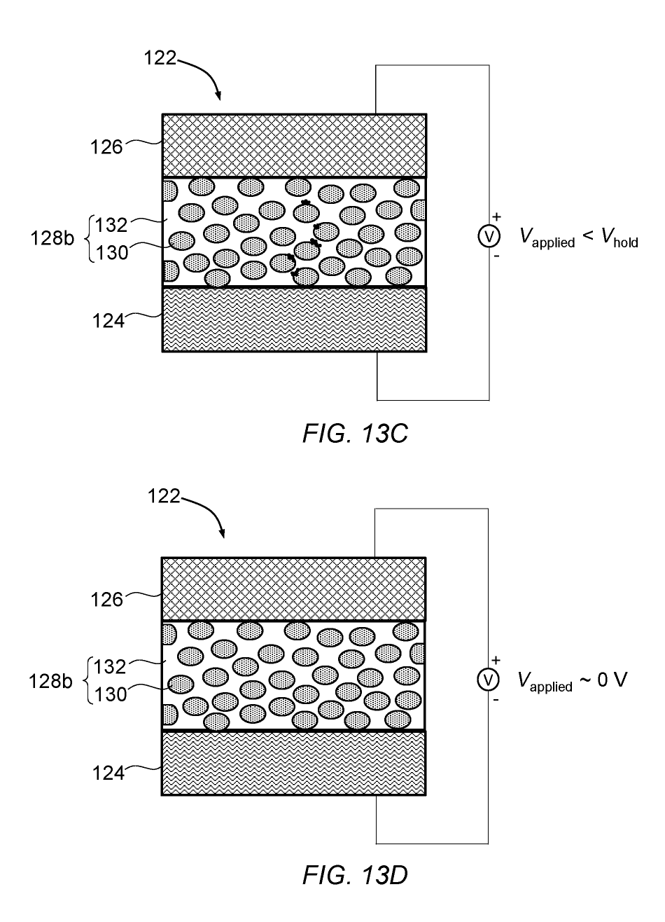

Without being bound to any theory, it is believed that one or more conductive paths or filaments are formed within the switching layer 128 when the applied voltage, V_{applied}, exceeds Vₜₕ as illustrated in FIG. 13A for the composite switching layer structure 128b, resulting in the two-terminal selector element 122 being in a highly conductive state. In response to the applied voltage that is greater than Vₜₕ, ions and/or ionic particles from at least one of the first and second electrodes 124 and 126 may migrate into the switching layer 128b to form conductive bridges between the conductive clusters 130, thereby forming one or more conductive paths between the first and second electrodes 124 and 126 through the switching layer 128b. Alternatively, ions and/or ionic particles from the conductive clusters 130 may migrate and form the conductive bridges between the conductive clusters 130 within the switching layer 128b. Therefore, the ions and/or ionic particles for forming conductive bridges may come from at least one of the first and second electrodes 124 and 126, or the conductive clusters 130, or both. It should be noted that there are various possible mechanisms that can cause ions and/or ionic particles to migrate, such as but not limited to electric field, electric current, and joule heating, in the presence of the applied voltage.

Referring back to FIG. 12A, as the voltage applied to the selector element 122 decreases from Vₚ to near a holding voltage, V_{hold}, that is lower than Vₜₕ, the current gradually decreases and the selector element 110 remains in the highly conductive state. The conductive paths previously formed in the switching layer 128b remain mostly intact as illustrated in FIG. 13B.

At or near V_{hold}, the current rapidly decreases and exhibits a highly non-linear behavior. As the voltage continues to decrease beyond V_{hold}, the current decrease becomes gradual again. When the voltage drops below V_{hold}, the conductive bridges disintegrate and the one or more conductive paths between the electrodes 124 and 126 break down as illustrated in FIG. 13C, returning the selector element 122 back to a semi-conducting or insulating state. At zero voltage, the conductive bridges disappear and the switching layer 128b remains in the original semi-conducting or insulating state as illustrated in FIG. 13D.

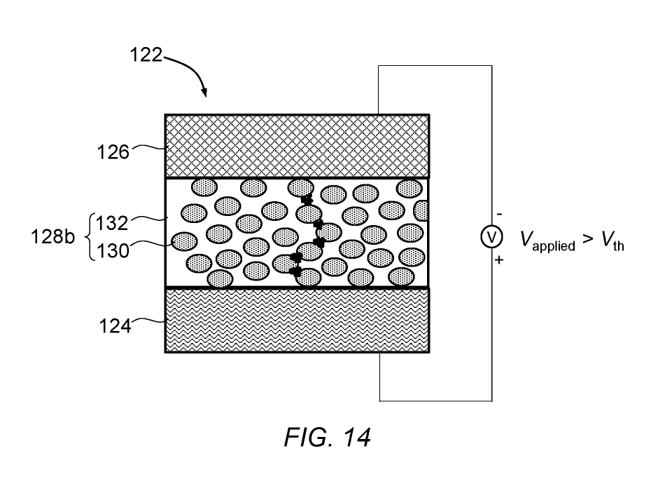

With continuing reference to FIG. 12A, the I-V response of the selector element 122 is characterized by a hysteresis behavior as the applied voltage is increased from zero to Vₚ and decreased back to zero again. The current response behaves like a step function as the applied voltage increases from zero to Vₚ with the sharp increase occurring at or near Vₜₕ. As the voltage decreases from Vₚ to zero, the current markedly decreases at or near V_{hold}, which is lower than Vₚ. The two-terminal selector element 122 is bi-directional as the polarity of the applied voltage may be reversed as illustrated in the I-V plot of FIG. 12A. The I-V response corresponding to the opposite polarity is substantially similar to that described above. When V_{applied} exceeds Vₜₕ, one or more conductive paths form between the electrodes 124 and 126 as shown in FIG. 14, resulting in the two-terminal selector element 122 being in the highly conductive state.

Alternatively, the two-terminal selector element 122 may exhibit a different I-V response as illustrated in FIG. 12B. The I-V plot of FIG. 12B differs from that of FIG. 12A in that the current remains relatively constant (compliance current, I_{cc}) even as the applied voltage decreases from Vₚ to V_{hold}. Therefore, the selector element 122 remains in the highly conductive state and the conductive paths previously formed in the switching layer 128b remain mostly intact as illustrated in FIG. 13B.

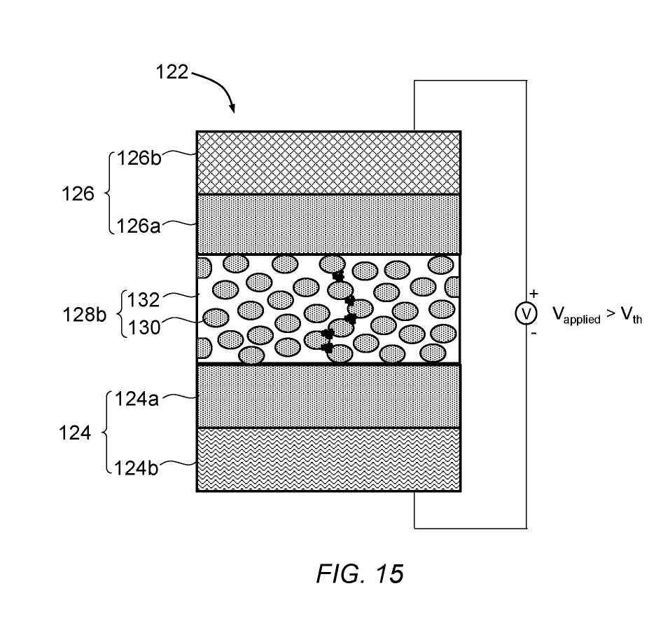

FIG. 15 shows another embodiment of the present invention as applied to the two-terminal selector element 122. The first electrode structure 124 of the two-terminal selector element 122 includes a first electrode layer 124a formed adjacent to the volatile switching layer structure 128a and a second electrode layer 124b formed adjacent to the first electrode layer 124a. The second electrode structure 126 of the two-terminal selector element 122 includes a first electrode layer 126a formed adjacent to the volatile switching layer structure 128a and a second electrode layer 126b formed adjacent to the first electrode layer 126a. Each of the first and second electrode layers 124a and 124b of the first electrode structure 124 and the first and second electrode layers 126a and 126b of the second electrode structure 126 may be made of any material as described above. For example and without limitation, the first electrode layers 124a and 126a may be made of titanium nitride (TiNₓ) and at least one of the second electrode layers 124b and 126b may be made of silver (Ag) or an alloy of silver and aluminum.

While the present invention has been shown and described with reference to certain preferred embodiments, it is to be understood that those skilled in the art will no doubt devise certain alterations and modifications thereto which nevertheless include the true spirit and scope of the present invention. Thus the scope of the invention should be determined by the appended claims and their legal equivalents, rather than by examples given.

What is claimed is:

1. A memory device comprising an array of memory cells, each of said memory cells including a memory element connected to a two-terminal selector element, said two-terminal selector element comprising a first electrode and a second electrode with a volatile switching layer interposed therebetween, said first electrode having a composition comprising a metal element and said second electrode having a composition comprising said metal element and aluminum element.

2. The memory device of claim 1, wherein said metal element is silver, copper, or nickel.

3. The memory device of claim 1, wherein said composition of said first electrode further comprises aluminum element.

4. The memory device of claim 1, wherein said second electrode is deposited onto said volatile switching layer during fabrication.

5. The memory device of claim 1, wherein said volatile switching layer is made of an insulator.

6. The memory device of claim 5, wherein said insulator is hafnium oxide, zirconium oxide, titanium oxide, or any combination thereof.

7. The memory device of claim 5, wherein said insulator is tantalum oxide, niobium oxide, magnesium oxide, aluminum oxide, or any combination thereof.

8. The memory device of claim 1, wherein said volatile switching layer has a composite structure comprising a plurality of conductive particles embedded in an insulating matrix.

9. The memory device of claim 8, wherein said insulating matrix is made of hafnium oxide, zirconium oxide, titanium oxide, or any combination thereof.

10. The memory device of claim 8, wherein said insulating matrix is made of tantalum oxide, niobium oxide, magnesium oxide, aluminum oxide, or any combination thereof.

11. The memory device of claim 8, wherein said plurality of conductive particles are made of silver, copper, nickel, or any combinations thereof.

12. The memory device of claim 8, wherein said plurality of conductive particles are made of zinc, titanium, tungsten, arsenic, or any combinations thereof.

13. The memory device of claim 1, wherein said volatile switching layer has a multilayer structure comprising one or more conductive layers interleaved with two or more insulating layers.

14. The memory device of claim 13, wherein said two or more insulating layers are made of hafnium oxide, zirconium oxide, titanium oxide, or any combination thereof.

15. The memory device of claim 13, wherein said two or more insulating layers are made of tantalum oxide, niobium oxide, magnesium oxide, aluminum oxide, or any combination thereof.

16. The memory device of claim 13, wherein said one or more conductive layers are made of silver, copper, nickel, or any combinations thereof.

17. The memory device of claim 13, wherein said one or more conductive layers are made of zinc, titanium, tungsten, arsenic, or any combinations thereof.

18. The memory device of claim 1, wherein each of said memory cells further includes an intermediate electrode interposed between said memory element and said two-terminal selector element.

19. The memory device of claim 1, wherein said memory element includes a magnetic free layer and a magnetic reference layer with an insulating tunnel junction layer interposed therebetween.

20. The memory device of claim 19, wherein said magnetic free layer has a variable magnetization direction substantially perpendicular to a layer plane thereof, said magnetic reference layer has a fixed magnetization direction substantially perpendicular to a layer plane thereof.
